(19) United States
(12) Patent Application Publication
(10) Pub. No.: US 2019/0357350 A1
(43) Pub. Date: Nov. 21, 2019

(54) WIRING BOARD AND METHOD FOR MANUFACTURING SAME

(71) Applicant: NEC Corporation, Minato-ku, Tokyo (JP)

(72) Inventor: Kazuhiro KASHIWAKURA, Tokyo (JP)

(73) Assignee: NEC Corporation, Minato-ku, Tokyo (JP)

(21) Appl. No.: 16/484,159

(22) PCT Filed: Feb. 28, 2018
(86) PCT No.: PCT/JP2018/007422

§ 371 Date: Aug. 7, 2019

(30) Foreign Application Priority Data
Mar. 2, 2017 (JP) 2017-039110

(51) Int. Cl. H05K 1/02; H05K 1/11

(52) U.S. Cl. CPC H05K 1/0248; H05K 1/024; H05K 1/115; H05K 1/0251

(57) ABSTRACT

The present invention addresses the problem of reducing a delay time difference between signals transmitted by means of a differential signal wires in a wiring board having glass cloth. A wiring board comprises: an insulating layer which includes fibers having a planar shape with translational symmetry with respect to two linearly independent, predetermined translational vectors, and a layer-like insulating material encapsulating the fibers; and through-holes formed at the starting and end points of a vector which is the sum of substantially integral multiples of the two translational vectors and which has the starting point on the planar shape.

### TECHNICAL FIELD

The present invention relates to a wiring board on which high-frequency signals are transmitted and, in particular, to a wiring board on which differential signals in a high frequency band are transmitted.

### BACKGROUND ART

As an information and communication society develops, data communication and signal processing are being performed with large capacities and at high speeds, and an increase in speed of signals to be transmitted is being advanced. As the speed of signals is increased, influences of losses and delays of signals when being transmitted on a wiring board can be no longer ignored. Therefore, a signal wire of an electronic device that processes a large amount of data at a high speed needs to be designed with a wire width and a wire length that satisfy required characteristics.

As a signal transmission speed exceeds 10 Giga bit per second (Gbps) and is increased to 28 Gbps, 56 Gbps, etc., differential signal wires are becoming mainstream as signal wires on a wiring board. Differential signals are transmitted through two signal wires as signals that are opposite in phase. However, due to influences of factors such as electrical characteristics of the signal wires and insulating layers, a difference in delay time is caused between the two signals that are opposite in phase, and a deviation from the opposite phase state occurs at an output side. Consequently, a situation occurs in which a semiconductor device or the like at the output side cannot properly detect signals. In other words, in order that differential signals may be properly processed at the output side on a wiring board on which the differential signals are transmitted, a difference in delay time between the two signals that are opposite in phase needs to be sufficiently suppressed.

In order to suppress losses and delays of signals on a wiring board, efforts are being made such as reducing permittivity of insulating materials that form the wiring board. This is because delay time τ is in relationship τ=✓εᵣ/CO (where εᵣ is a relative permittivity and CO is the speed of light). On the other hand, in a wiring board such as a printed board, glass cloth is sometimes used as a structural material for maintaining mechanical strength of the board. Glass fibers of glass cloth have a higher relative permittivity than insulating materials having a reduced permittivity.

Glass cloth used in a printed board is cloth having bundles of a plurality of glass fibers that are plainly woven in a lengthwise direction and a widthwise direction. There are intervals between glass fiber bundles arranged in the lengthwise direction and widthwise direction. Accordingly, a signal transmitted through a signal wire formed on a printed board passes through a portion where glass cloth exists and a portion consisting only of a resin being an insulating material. Because the relative permittivity of the glass fibers of the glass cloth and a relative permittivity of the resin differ from each other, differences in amount of delay and amount of loss of the signal may be caused between passing through the glass fiber portion and passing through the portion consisting only of the resin. Consequently, a difference in delay time is caused between signals transmitted through two differential signal wires that pass through different portions.

PTLs 1 and 2 disclose techniques of suppressing a difference in delay time between signals transmitted through two differential signal wires. PTL 1 claims that a difference in delay time between differential signal wires can be suppressed by setting a signal wire width to be 75% to 95% of an interval between glass fiber bundles. PTL 2 claims that a difference in delay time between differential signal wires can be suppressed by setting an interval between differential signal wires to be an integral multiple of an interval between glass fiber bundles.

### CITATION LIST

### Patent Literature

[PTL 1] Japanese Unexamined Patent Application Publication No. 2014-130860

[PTL 2] International Publication WO 2016/117320

### SUMMARY OF INVENTION

### Technical Problem

Multilayer wiring that uses through-holes is essential to a wiring board that achieves a signal transmission speed higher than 50 Gbps and on which an optical module that constitutes an interface with a communication line and a semiconductor device such as a large scale integrated circuit (LSI) are mounted.

However, while PTLs 1 and 2 disclose solutions relating to wiring, such as a wire width and an interval between wires, in order to suppress a delay time difference between signals transmitted through differential signal wires on a wiring board having glass cloth, neither of PTL 1 nor PTL 2 discloses solutions relating to through-holes. When a wire passes through a through-hole, a signal delay occurs in the through-hole as well. Accordingly, when differential signal wires pass through through-holes, a difference in delay time is caused between transmitted signals.

The present invention has been made in light of the problem described above and an object of the present invention is to provide a wiring board having glass cloth, the wiring board including through-holes that is able to reduce a delay time difference between signals transmitted through differential signal wires.

### Solution to Problem

In one aspect of the invention, a wiring board includes:

an insulating layer including a fabric having a planar shape that is translationally symmetric with respect to predetermined two linearly independent translation vectors and a layered insulating material encapsulating the fabric; and

through-holes formed at starting and end points of a vector that is a sum of substantially integral multiples of each of the two translation vectors and has a starting point on the planar shape.

In one aspect of the invention, a wiring board manufacturing method includes:

forming an insulating layer by disposing a fabric that has a planar shape that is translationally symmetric with respect to predetermined two linearly independent translation vectors and encapsulating the fabric by a layered insulating material; and

forming through-holes at starting and end points of a vector that is a sum of substantially integral multiples of each of the two translation vectors and has a starting point on the planar shape.

### Advantageous Effects of Invention

The present invention is able to provide a wiring board having glass cloth, the wiring board including through-holes that is able to reduce a delay time difference between signals transmitted through differential signal wires.

### BRIEF DESCRIPTION OF DRAWINGS

FIG. 1 is a diagram illustrating a configuration of a wiring board according to a first example embodiment of the present invention.

FIG. 2 is a diagram illustrating a configuration of a wiring board according to a second example embodiment of the present invention.

FIG. 3 is a diagram for explaining advantageous effects of the configuration of the wiring board according to the second example embodiment of the present invention.

FIG. 4 is a diagram illustrating a configuration for calculating insertion losses in differential signals in through-holes of the wiring board according to the second example embodiment of the present invention.

FIG. 5 is a diagram illustrating results acquired by calculating insertion losses in differential signals in the through-holes of the wiring board according to the second example embodiment of the present invention.

FIG. 6 is a diagram illustrating results acquired by calculating intervals between glass fiber bundles from standard values of densities of glass fiber bundles.

FIG. 7 is a diagram illustrating a configuration of a wiring board according to a variation of the second example embodiment of the present invention.

### EXAMPLE EMBODIMENT

Example embodiments of the present invention will be described below in detail with reference to the drawings. In the example embodiments described below, technically preferable limitations are provided for carrying out the invention. However, the scope of the invention is not limited to the following descriptions.

### First Example Embodiment

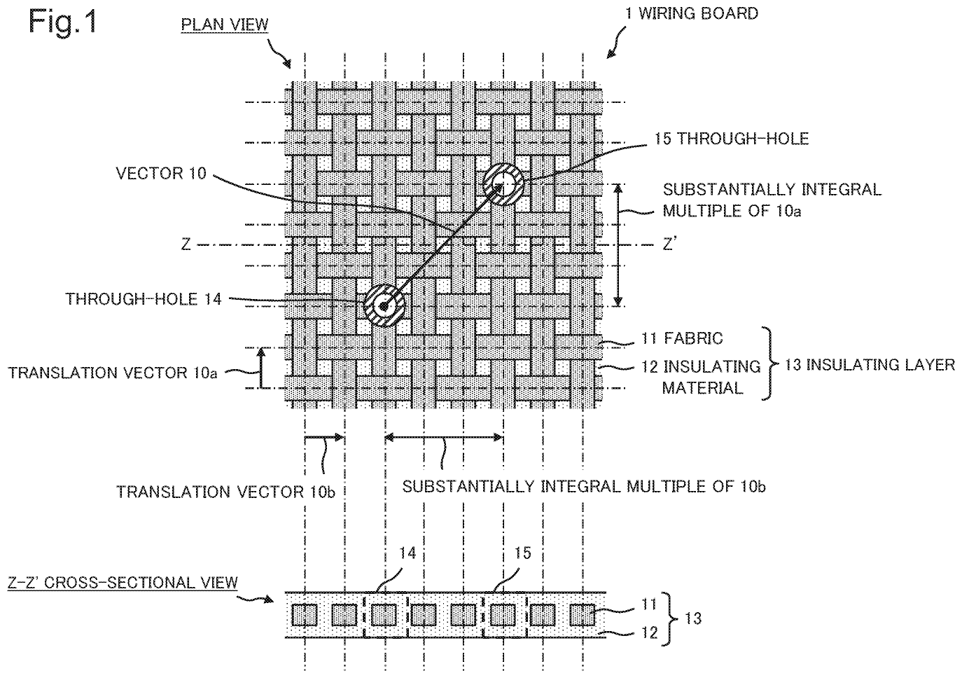

FIG. 1 is a diagram illustrating a configuration of a wiring board according to a first example embodiment of the present invention. FIG. 1 illustrates a plan view and a Z-Z′ cross-sectional view of wiring board 1 according to the present example embodiment. Wiring board 1 includes insulating layer 13 including fabric 11 each having a planar shape that is translationally symmetric with respect to predetermined two linearly independent translation vectors 10a, 10b, and layered insulating material 12 encapsulating fabric 11. Wiring board 1 further includes through-holes 14, 15 formed at starting and end points of vector 10 that is a sum of substantially integral multiples of two translation vectors 10a, 10b and has the starting point on the planar shape.

Wiring board 1 can make influences of permittivities of fabric 11 and insulating material 12 on each of through-hole 14 and through-hole 15 equivalent. As a result, delay times of signals transmitted to through-hole 14 and through-hole 15 can be made equivalent and a difference between the both can be reduced. Consequently, when through-hole 14 and through-hole 15 are connected to differential signal wires, a delay time difference between signals transmitted through the differential signal wires can be reduced.

The example embodiment as described above can provide a wiring board having glass cloth, the wiring board including through-holes that can reduce a delay time difference between signals transmitted through differential signal wires.

### Second Example Embodiment

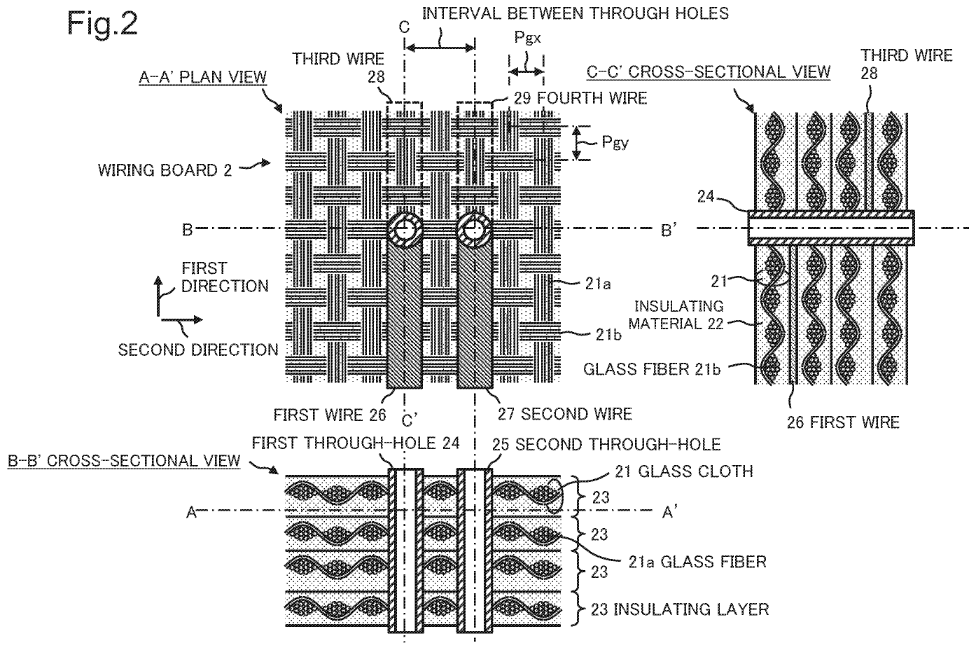

FIG. 2 is a diagram illustrating a configuration of a wiring board according to a second example embodiment of the present invention. Wiring board 2 according to the present example embodiment is a multi-layer wiring board including a plurality of insulating layers 23, wires (first to fourth wires) provided between insulating layers 23, and through-holes (first and second through-holes) that connect wires provided across insulating layers 23.

Each of insulating layers 23 includes glass cloth 21 and insulating material 22. While four insulating layers 23 are provided as illustrated in a B-B′ cross-sectional view and a C-C′ cross-sectional view in FIG. 2, the present example embodiment is not limited thereto. Any number of insulating layers 23 may be provided.

Glass cloth 21 functions as a structural material for reinforcing a mechanical strength of insulating layers 23. As illustrated in an A-A′ plan view, glass cloth 21 is cloth that is plainly woven in such a way that directions of a bundle of glass fibers 21a and a bundle of glass fibers 21b are perpendicular to each other. The directions of glass fibers 21a, 21b here means directions parallel to long axes of glass fibers 21a and 21b. In the present example embodiment, it is assumed that the two directions perpendicular to each other as illustrated in the A-A′ plan view are referred to as a first direction and a second direction, respectively, glass fibers in the first direction are glass fibers 21a, and glass fibers in the second direction are glass fibers 21b.

Note that the bundle of glass fibers 21a and the bundle of glass fibers 21b may be substantially perpendicular to each other. Substantially perpendicular here means a perpendicular state where a deviation from perpendicularity due to an error or a variation during manufacturing is tolerated.

In glass cloth 21, the bundles of glass fibers 21a having the long axis in the first direction and having the same shape such as the same width and thickness are arranged substantially in parallel in a planar view at substantially equal intervals. An interval between the bundles of glass fibers 21a is a distance between centers of the bundles of glass fibers 21a, wherein multiple glass fibers form one bundle. In the present example embodiment, the interval between the bundles of glass fibers 21a having the long axis in the first direction is denoted by Pgx.

Further, substantially parallel here means a state where bundles of glass fibers along the same direction are arranged without intersecting each other and with their long axes being aligned with each other. It is more desirable here that the bundles of glass fibers are parallel to each other. Substantially equal intervals mean a state where a deviation from equal intervals due to an error or a variation during manufacturing is tolerated.

Further, in glass cloth 21, bundles of glass fibers 21b having the long axis in the second direction that is perpendicular to the first direction and having the same shape such as the same width and thickness are arranged substantially in parallel in a planar view at substantially equal intervals. In the present example embodiment, the interval between the bundles of glass fibers 21b having the long axis in the second direction is denoted by Pgy.

Insulating material 22 is filled between glass fibers 21a, 21b that constitute glass cloth 21 and is formed in layers in such a way as to encapsulate glass cloth 21. A resin can be used as insulating material 22 and, for example, an epoxy resin can be used.

Glass cloth 21 included in each of the plurality of insulating layers 23 has Pgx and Pgy that are equal among insulating layers 23. Insulating layers 23 are stacked in such a way that bundles of glass fibers 21a and bundles of glass fibers 21b are overlapped with each other among insulating layers 23 in a planar view. However, the present example embodiment is not limited to this. Insulating layers 23 may be stacked in such a state that a bundle of glass fibers 21a and a bundle of glass fibers 21b are out of alignment among insulating layers 23 in a planar view as long as the first direction and the second direction of glass cloth 21 are aligned.

Further, glass cloth 21 may be omitted from one or more insulating layers 23 or may be provided in all insulating layers 23, depending on a mechanical strength required of wiring board 2.

Insulating layers 23 according to the present example embodiment are equivalent to insulating layer 13 according to the first example embodiment. Further, the bundles of glass fibers 21a and the bundles of glass fibers 21b that constitute glass cloth 21 according to the present example embodiment are equivalent to fabric 11 according to the first example embodiment. Insulating material 22 according to the present example embodiment is equivalent to insulting material 12 according to the first example embodiment. First through-hole 24 and second through-hole 25 according to the present example embodiment, which will be described later, are equivalent to through hole 14 and through hole 15 according to the first example embodiment, respectively.

First through-hole 24 and second through-hole 25 each have a structure in which a conductor such as a copper is formed in inner walls of holes provided in a direction of thickness of insulating layers 23. Further, the hole may be filled with a conductor. First through-hole 24 and second through-hole 25 can electrically connect first wire 26 with third wire 28, and second wire 27 with fourth wire 29, respectively, which are provided on insulating layers 23 different from each other.

Inside diameters of first through-hole 24 and second through-hole 25 and thicknesses of the conductor formed on the inner walls of first through-hole 24 and second through-hole 25, widths and thicknesses of first wire 26 and second wire 27, and third wire 28 and fourth wire 29 are set in such a way as to provide characteristic impedances that depend on a design of the wiring board. The through-holes and wires are formed by using a copper. The material is not limited to a copper and the through-holes and wires may be formed of other metals such as Al, W or Au or may be formed of an alloy of a plurality of metals.

First through-hole 24 and second through-hole 25 are provided along the second direction with an interval that is a positive integral multiple of interval Pgx between bundles of glass fibers 21a. Alternatively, first through-hole 24 and second through-hole 25 are provided along the first direction with an interval that is a positive integral multiple of interval Pgy between bundles of glass fibers 21b. FIG. 2 illustrates a case where first through-hole 24 and second through-hole 25 are provided along the second direction. An interval between first through-hole 24 and second through-hole 25 means a distance between centers of first through-hole 24 and second through-hole 25.

First wire 26 and second wire 27 are provided in parallel to each other. First wire 26 connects to first through-hole 24 and second wire 27 connects to second through-hole 25. While long axes of first wire 26 and second wire 27 are provided in parallel to the first direction as illustrated in the A-A′ plan view, the present example embodiment is not limited to this. The long axes of first wire 26 and second wire 27 may be skewed from the first direction as long as the long axes are parallel to each other.

Third wire 28 and fourth wire 29 are provided in parallel to each other on insulating layer 23 that is different from insulating layer 23 on which first wire 26 and second wire 27 are provided. Third wire 28 connects to first through-hole 24 and fourth wire 29 connects to second through-hole 25. While long axes of third wire 28 and fourth wire 29 are provided in parallel to the first direction as illustrated in the A-A′ plan view, the present example embodiment is not limited to this. The long axes of third wire 28 and fourth wire 29 may be skewed from the first direction as long as the long axes are parallel to each other.

With the connections described above, a set of first wire 26, first through-hole 24, and third wire 28, and a set of second wire 27, second through-hole 25, and fourth wire 29 allow transmission of differential signals across different insulating layers 23. Specifically, when the set of first wire 26, first through-hole 24, and third wire 28 transmits a positive signal out of differential signals, the set of second wire 27, second through-hole 25, and fourth wire 29 can transmit a negative signal out of the differential signals.

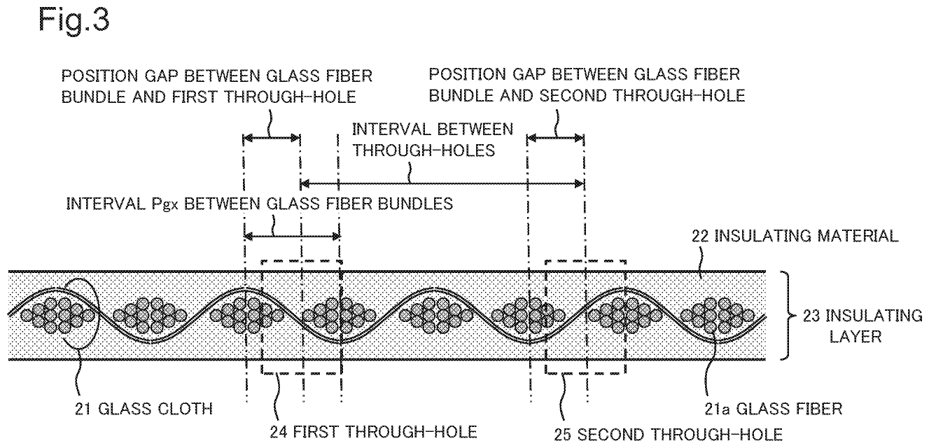

FIG. 3 is a diagram for explaining advantageous effects of the configuration of wiring board 2 according to the present example embodiment. In FIG. 3, first through-hole 24 and second through-hole 25 are provided along the second direction with an interval of a positive integral multiple of Pgx. This makes a position gap between a bundle of glass fibers 21a and first through-hole 24 equivalent to a position gap between a bundle of glass fibers 21a and second through-hole 25. As a result, influences of an electrical characteristic of insulating layer 23 on delay of signals are made equivalent between first through-hole 24 and second through-hole 25, a difference between delay times is reduced, and an insertion loss of differential signals is reduced. Note that the same applies to a case where first through-hole 24 and second through-hole 25 are provided along the first direction.

Since first through-hole 24 and second through-hole 25 are provided along the second direction with an interval of a positive integral multiple of Pgx, positional relationships of first wire 26 and second wire 27 through which differential signals are transmitted with bundles of glass fibers 21a are made equivalent. As a result, the influences of an electrical characteristic of insulating layer 23 on delay of signals are made equivalent between first wire 26 and second wire 27, a difference between delay times is reduced, and an insertion loss of differential signals is reduced. Note that the same applies to a case where first through-hole 24 and second through-hole 25 are provided along the first direction.

Further, since first through-hole 24 and second through-hole 25 are provided along the second direction with an interval of a positive integral multiple of Pgx, positional relationships of third wire 28 and fourth wire 29 through which differential signals are transmitted with bundles of glass fibers 21a are made equivalent. As a result, the influences of an electrical characteristic of insulating layer 23 on delay of signals are made equivalent between third wire 28 and fourth wire 29, a difference between delay times is reduced, and an insertion loss of differential signals are reduced. Note that the same applies to a case where first through-hole 24 and second through-hole 25 are provided along the first direction.

Assuming that the interval between first through-hole 24 and second through-hole 25 along the second direction is denoted by Pdx, then through-hole interval Pdx is set such that Pdx=Nx×Pgx is satisfied. Nx is a positive integer. Taking into account manufacturing errors, it is desirable that a value of through-hole interval Pdx, which is calculated from interval Pgx between bundles of glass fibers 21a, is accurate to the second decimal place or beyond in millimeters. Accordingly, a value of Nx which defines the magnitude of an integer multiple does not need to be exactly an integer and a value that is different from an integer by a decimal to the second decimal place or beyond can also be considered to be an integer. In the present example embodiment, therefore, a substantially integral multiple that is a value different from an integer by a decimal to the second decimal place or beyond is also referred to as an integral multiple. Note that the same applies to a case where first through-hole 24 and second through-hole 25 are provided along the first direction.

Note that when a plurality of insulating layers 23 are stacked, bundles of glass fibers 21a that have the long axis in the first direction of glass cloth 21 and bundles of glass fibers 21b that have the long axis in the second direction may be stacked out of alignment with each other in a planar view as long as each of Pgx and Pgy of glass cloth 21 is equivalent among insulating layers 23. Even in such a stacked state, the positional relationships between glass cloth 21 and through-holes in each insulating layer 23 are made equivalent between first through-hole 24 and second through-hole 25. As a result, the influences of an electrical characteristic of insulating layer 23 on delay of signals are made equivalent between first through-hole 24 and second through-hole 25, a delay time difference is reduced, and an insertion loss of differential signals is reduced.

Further, since a position of glass cloth 21 may be out of alignment among insulating layers 23, the need for high-precision alignment is eliminated and therefore manufacturing cost can be reduced.

Note that a bundle of glass fibers 21a and a bundle of glass fibers 21b do not necessarily need to be perpendicular to each other. Even when a bundle of glass fibers 21a and a bundle of glass fibers 21b are skewed from perpendicularity, first through-hole 24 and second through-hole 25 are provided along a perpendicular direction of glass fibers 21a with an interval that is a positive integral multiple of Pgx. This makes the positional relationships of glass cloth 21 with first through-hole 24 and second through-hole 25 equivalent.

A method of manufacturing wiring board 2 according to the present example embodiment will be described next.

First, insulating layer 23 including glass cloth 21 and insulating material 22 that is applied in such a way as to fill gaps in glass cloth 21 and cover glass cloth 21 is formed. Glass cloth 21 is formed by plainly weaving bundles of glass fibers 21a that have a long axis in a first direction and are arranged in a second direction substantially perpendicular to the first direction with an interval of Pgx substantially in parallel to each other in a planar view and bundles of glass fibers 21b that have a long axis in the second direction and are arranged in the first direction with an interval of Pgy substantially in parallel to each other in a planar view.

Then, a plurality of insulating layers 23 are stacked with the first direction and the second direction of glass cloth 21 being aligned among insulating layers 23.

At this point in time, first wire 26 and second wire 27 are further formed substantially in parallel on a surface of one insulating layer 23, and third wire 28 and fourth wire 29 are further formed substantially in parallel on a surface of another insulating layer 23, and insulating layers 23 are stacked. First wire 26 and third wire 28 are formed in such a way as to connect to first through-hole 24 to be described later, and second wire 27 and fourth wire 29 are formed in such a way as to connect to second through-hole 25 to be described later.

Then, first through-hole 24 which connects to first wire 26 and third wire 28 and second through-hole 25 which connects to second wire 27 and fourth wire 29 are formed across stacked insulating layers 23. Here, first through-hole 24 and second through-hole 25 are provided in the second direction with an interval of a substantially positive integral multiple of Pgx. Alternatively, first through-hole 24 and second through-hole 25 are provided in the first direction with an interval of a substantially positive integral multiple of Pgy.

In the method of manufacturing wiring board 2 described above, the position of glass cloth may not be able to be checked when through-holes and wires are formed. Glass cloth 21 is covered with insulating material 22 and cannot be checked from a surface thereof. On the other hand, the first direction and the second direction of glass cloth 21 can be checked by indications of the directions on a surface of insulating layer 23 or the like. In the present manufacturing method, through-holes can be provided in the second direction with an interval of a substantially positive integral multiple of Pgx or provided in the first direction with an interval of a substantially positive integral multiple of Pgy even when the position of glass cloth cannot be checked.

Wiring board 2 manufactured as described above can reduce a delay time difference when differential signals are transmitted through the set of first through-hole 24, first wire 26 and third wire 28 and the set of second through-hole 25, second wire 27 and fourth wire 29.

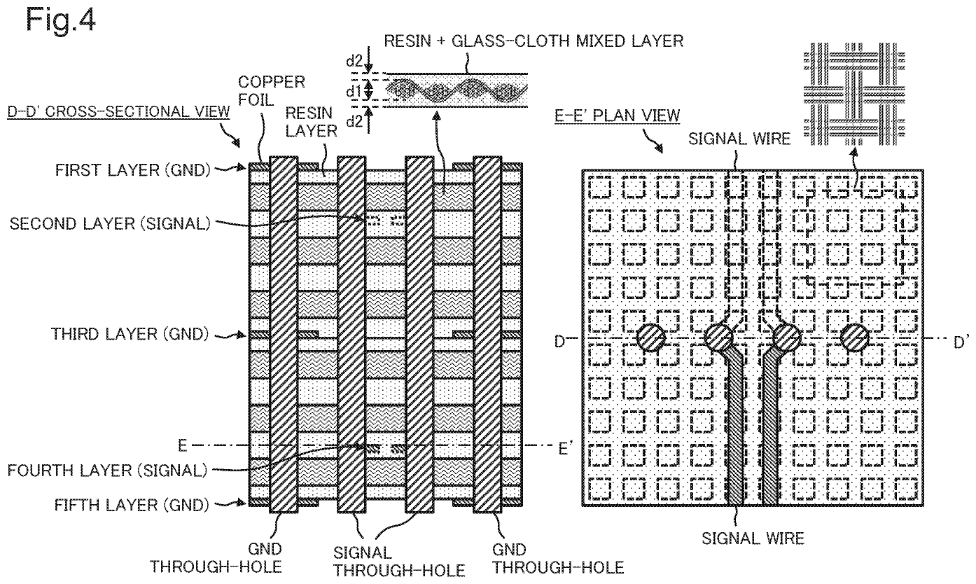

FIG. 4 is a diagram illustrating a configuration for analyzing insertion losses in differential signals in through-holes of the wiring board according to the present example embodiment. The wiring board used in the analysis has five conducting layers (copper foils), wherein first, third, and fifth layers are set as ground (GND) layers and second and fourth layers are set as signal wiring layers. Insulating layers are structured in such a way that an insulating layer made of a resin and glass cloth and an insulating layer made only of a resin are alternately stacked.

In an insulating layer made of a resin and glass cloth, an interval between glass fiber bundles of glass cloth is set to be 0.5 mm. The width of a resin portion is set to be 40% of the interval between glass fiber bundles. Thickness d1 of the glass cloth and thickness d2 of the resin portion are set to be such that d1=2×d2. A width of a signal wire is set to be 80 μtm and an interval between a positive-signal differential signal wire and a negative-signal differential signal wire is set to be 0.5 mm.

Signal through-holes that connect a signal wire in a second layer and a signal wire in a fourth layer and GND through-holes that connect GND are provided as through-holes. The GND through-holes are provided in order to adjust characteristic impedances of the signal through-holes. Both of the GND through-holes are disposed on a line extended from the line of the signal through-holes with an interval from both of the signal through-holes which is equal to an interval between the signal through-holes.

The interval between the signal through-holes is set to be 1 mm, which is twice as great as 0.5 mm that is the interval between glass fiber bundles. Both of the GND through-holes are provided with an interval of 1 mm from both of the signal through-holes.

As an example to be compared with the configuration according to the present example embodiment as described above, a configuration is provided in which the interval between signal through-holes is made 1.33 times as great as the interval between glass fiber bundles by setting the interval between the glass fiber bundles of glass cloth to be 0.75 mm.

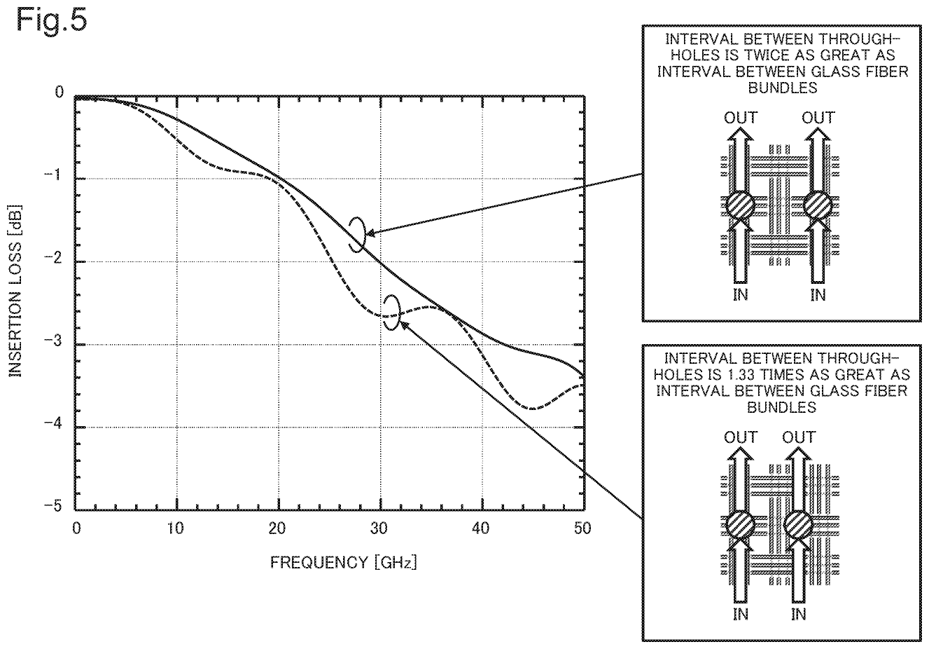

FIG. 5 is a diagram illustrating results acquired by calculating insertion losses of differential signals in the signal through-holes of the wiring board in FIG. 4. Specifically, a positive differential signal and a negative differential signal are input into left and right signal through-holes, respectively, and an insertion loss is calculated from a delay time of each of the positive signal and the negative signal output from the signal through-holes. FIG. 5 illustrates results of the calculation.

In a case where the interval between the signal through-holes is twice as great as the interval between the glass fiber bundles, which is equivalent to the present example embodiment, the insertion loss has a characteristic of smoothly attenuating with respect to frequency. In contrast, in a case where the interval between the signal through-holes is 1.33 times as great as the interval between glass fiber bundles, which is not equivalent to the present example embodiment, the insertion loss attenuates while significantly fluctuating with respect to frequency. The loss increases and transmission characteristic degradation is remarkable especially at and around 30 GHz and 45 GHz.

The results in FIG. 5 as described above are attributed to a relationship of the interval between signal through-holes with the interval between the glass fiber bundles. In the present example embodiment in which the interval between signal through-holes is a positive integral multiple of the interval between glass fiber bundles, the positional relationships of the glass fiber bundles with both of the signal through-holes are equivalent. As a result, the influences of an electrical characteristic of an insulating layer on delay of signals are made equivalent between both of the signal through-holes, a delay time difference is reduced, and an insertion loss of differential signals is reduced.

In contrast, in a case where the interval between the signal through-holes is not a positive integral multiple of the interval between glass fiber bundles, the positional relationships of the glass fiber bundles with both of the signal through-holes are different. As a result, the influences of an electrical characteristic of an insulting layer on delay of signals differ between both signal through-holes, a delay time difference increases, and an insertion loss of differential signals increases.

Note that even in the case where the interval between the signal through-holes is not a positive integral multiple of the interval between glass fiber bundles, the positional relationships between glass cloth and both signal through-holes can be made equivalent by identifying set positions of signal through-holes with respect to glass cloth. However, as described above, when through-holes and wires are formed during manufacturing of the wiring board, the position of glass cloth cannot be checked. Accordingly, the set positions of signal through-holes with respect to the glass cloth cannot be identified and therefore actual manufacturing is impossible.

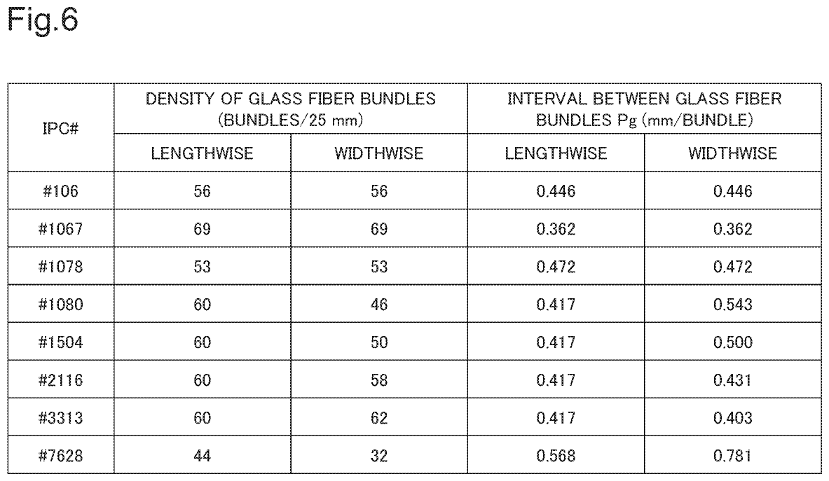

Note that the interval between glass fiber bundles of glass cloth can be acquired from a standard value of density of glass fiber bundles of a wiring board. FIG. 6 is a diagram illustrating results acquired by calculating intervals between glass fiber bundles from standard values of density of glass fiber bundles. Standards for the density of glass fiber bundles is specified in Association Connecting Electronics Industries (IPC; previously called Institute for Interconnecting and Packaging Electronics Circuits) and IPC# in FIG. 6 indicates the standards.

The density of glass fiber bundles in lengthwise and widthwise directions of glass cloth formed by plain-weave is indicated for each IPC#. For example, the lengthwise direction corresponds to the first direction and the widthwise direction corresponds to the second direction. The intervals between glass fiber bundles are values in the lengthwise direction and widthwise direction calculated from densities of glass fiber bundles. In the analysis of insertion loss in FIGS. 4 and 5 described previously, the interval between glass fiber bundles is set at 0.5 mm, which is within a range of values in FIG. 6, and therefore, it can be said to be a reasonable setting.

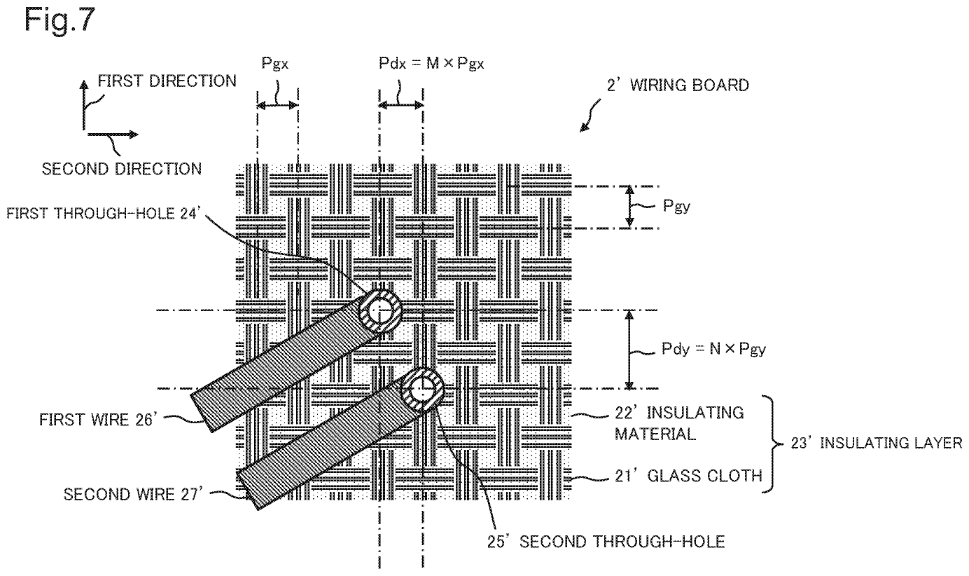

FIG. 7 is a diagram illustrating a configuration of a wiring board according to a variation of the present example embodiment. Glass cloth 21′ and insulating material 22′ constituting insulating layer 23′ of wiring board 2′ are the same as glass cloth 21 and insulating material 22 constituting insulating layer 23 of wiring board 2.

In wiring board 2′, regarding an interval between first through-hole 24′ and second through-hole 25′, a component (Pdx) of the interval in the second direction is a positive integral multiple of the interval (Pgx) between glass fiber bundles, and a component (Pdy) of the interval in the first direction is a positive integral multiple of the interval (Pgy) between glass fiber bundles. Specifically, the interval between first through-hole 24′ and second through-hole 25′, Pd=✓(Pdx²+Pdy²) satisfies

Pdx=M×Pgx (where M is a positive integer) and
Pdy=N×Pgy (where N is a positive integer).

First wire 26′ and second wire 27′ are provided in parallel to each other. First wire 26′ connects to first through-hole 24′ and second wire 27′ connects to second through-hole 25′.

With the connections described above, a set of first wire 26′ and first through-hole 24′, and a set of second wire 27′ and second through-hole 25′ allow transmission of differential signals across different insulating layers 23. Specifically, the set of first wire 26′ and first through-hole 24′ can transmit a positive signal out of differential signals and the set of second wire 27′ and second through-hole 25′ can transmit a negative signal out of the differential signals. Note that wires that are equivalent to third wire 28 and fourth wire 29 in FIG. 2 are omitted from FIG. 7.

By providing first through-hole 24′ and second through-hole 25′ in such a way that Pdx and Pdy described above are satisfied, the positional relationship between glass cloth 21′ and first through-hole 24′ and the positional relationship between glass cloth 21′ and second through-hole 25′ are made equivalent. As a result, influences of an electrical characteristic of insulating layer 23′ on delay of signals are made equivalent between first through-hole 24′ and second through-hole 25′, a delay time difference between the both is reduced, and an insertion loss of differential signals is reduced.

Since first through-hole 24′ and second through-hole 25′ are provided in such a way that Pdx and Pdy described above are satisfied, the positional relationship of first wire 26′ and second wire 27′ through which differential signals are transmitted with glass cloth 21′ are made equivalent. As a result, the influences of an electrical characteristic of insulating layer 23′ on delay of signals are made equivalent between first wire 26′ and second wire 27′, a delay time difference between both wires is reduced, and an insertion loss of differential signals is reduced. Note that the same applies to wires equivalent to third wire 28 and fourth wire 29 in FIG. 2, which are omitted from FIG. 7.

Note that while glass fibers that constitute glass cloth 21, 21′ in wiring board 2 and wiring board 2′ according to the present example embodiment are illustrated and described as being linear, the present example embodiment is not limited to this. Glass fibers may be curved as long as glass cloth has a planar shape that is translationally symmetric with respect to predetermined two linearly independent translation vectors.

Further, while glass cloth in which lengthwise glass fibers and widthwise glass fibers are perpendicular to each other has been illustrated and described, the present example embodiment is not limited to this. The lengthwise glass fibers and widthwise glass fibers do not need to be perpendicular to each other as long as the glass cloth has a planar shape that is translationally symmetric with respect to predetermined two linearly independent translation vectors.

Further, while glass cloth that has a structure made by plainly weaving lengthwise and widthwise glass fibers has been illustrated and described, the present example embodiment is not limited to this. Glass cloth does not need to have a structure made by plainly weaving lengthwise and widthwise glass fibers, as long as the glass cloth has a planar shape that is translationally symmetric with respect to predetermined two linearly independent translation vectors.

As described above, the wiring board according to the present embodiment can make influences of an electrical characteristic such as permittivity of an insulating layer on a first through-hole and a second through-hole equivalent. As a result, delay times of signals transmitted to the first through-hole and the second through-hole can be made equivalent and a difference between the both can be reduced. Consequently, when the first through-hole and the second through-hole are connected to differential signal wires, a delay time difference between signals transmitted through the differential signal wires can be reduced.

The present example embodiment as described above can provide a wiring board having glass cloth, the wiring board including through-holes that can reduce a delay time difference between signals transmitted through differential signal wires.

The present invention is not limited to the example embodiments described above and various variations are possible within the scope of the present invention described in claims and those variations also fall within the scope of the present invention.

The whole or part of the example embodiments disclosed above can be described as, but not limited to, the following supplementary notes.

### Supplementary Note 1

A wiring board comprising:

an insulating layer including a fabric having a planar shape that is translationally symmetric with respect to predetermined two linearly independent translation vectors and a layered insulating material encapsulating the fabric; and

through-holes formed at starting and end points of a vector that is a sum of substantially integral multiples of each of the two translation vectors and has a starting point on the planar shape.

### Supplementary Note 2

The wiring board according to supplementary note 1, wherein the two translation vectors are substantially perpendicular.

### Supplementary Note 3

The wiring board according to supplementary note 1 or 2, further comprising ground through-holes each provided on a line extended from the vector with a distance substantially equal to the vector from each of the through-holes at the starting and end points.

### Supplementary Note 4

The wiring board according to any one of supplementary notes 1 to 3, wherein a plurality of the insulating layers are stacked.

### Supplementary Note 5

The wiring board according to supplementary note 4, further comprising:

a pair of first wires provided substantially in parallel on a surface of the insulating layer; and

a pair of second wires provided substantially in parallel on a surface of another insulating layer,

wherein:

one of the pair of first wires and one of the pair of second wires connect to the through-hole at the starting point; and

another of the pair of first wires and another of the pair of second wires connect to the through-hole at the end point.

### Supplementary Note 6

The wiring board according to supplementary note 5, wherein

a set of the one of the pair of first wires, the one of the pair of second wires, and the through-hole at the starting point, and

a set of the another of the pair of first wires, the another of the pair of second wires, and the through-hole at the end point transmit differential signals.

### Supplementary Note 7

A wiring board manufacturing method comprising:

forming an insulating layer by disposing a fabric that has a planar shape that is translationally symmetric with respect to predetermined two linearly independent translation vectors and encapsulating the fabric by a layered insulating material; and

forming through-holes at starting and end points of a vector that is a sum of substantially integral multiples of each of the two translation vectors and has a starting point on the planar shape.

### Supplementary Note 8

The wiring board manufacturing method according to supplementary note 7, wherein the two translation vectors are substantially perpendicular.

### Supplementary Note 9

The wiring board manufacturing method according to supplementary note 7 or 8, further comprising forming each of ground through-holes on a line extended from the vector with a distance substantially equal to the vector from each of the through-holes at the starting and end points.

### Supplementary Note 10

The wiring board manufacturing method according to any one of supplementary notes 7 to 9, further comprising stacking a plurality of the insulating layers.

### Supplementary Note 11

The wiring board manufacturing method according to supplementary note 10, further comprising:

forming a pair of first wires substantially in parallel on a surface of the insulating layer;

forming a pair of second wires substantially in parallel on a surface of another insulating layer;

connecting one of the pair of first wires and one of the pair of second wires to the through-hole at the starting point; and

connecting another of the pair of first wires and another of the pair of second wires to the through-hole at the end point.

### Supplementary Note 12

The wiring board manufacturing method according to claim 11, wherein a set of the one of the pair of first wires, the one of the pair of second wires, and the through-hole at the starting point, and a set of the another of the pair of first wires, the another of the pair of second wires, and the through-hole at the end point transmit differential signals.

This application is based upon and claims the benefit of priority from Japanese Patent Application No. 2017-39110 filed on Mar. 2, 2017, the disclosure of which is incorporated herein in its entirety by reference.

### REFERENCE SIGNS LIST

1, 2, 2′ Wiring board

10 Vector

10a, 10b Translation vector

11 Fabric

12 Insulating material

13 Insulating layer

14 Through-hole

15 Through-hole

21, 21′ Glass cloth

21a, 21b Glass fiber

22, 22′ Insulating material

23, 23′ Insulating layer

24, 24′ First through-hole

25, 25′ Second through-hole

26, 26′ First wire

27, 27′ Second wire

28 Third wire

29 Fourth wire

What is claimed is:

1. A wiring board comprising:
an insulating layer including a fabric having a planar shape that is translationally symmetric with respect to predetermined two linearly independent translation vectors and a layered insulating material encapsulating the fabric; and
through-holes formed at starting and end points of a vector that is a sum of substantially integral multiples of each of the two translation vectors and has a starting point on the planar shape.

2. The wiring board according to claim 1, wherein the two translation vectors are substantially perpendicular.

3. The wiring board according to claim 1, further comprising ground through-holes each provided on a line extended from the vector with a distance substantially equal to the vector from each of the through-holes at the starting and end points.

4. The wiring board according to claim 1, wherein a plurality of the insulating layers are stacked.

5. The wiring board according to claim 4, further comprising:
a pair of first wires provided substantially in parallel on a surface of the insulating layer; and
a pair of second wires provided substantially in parallel on a surface of another insulating layer,
wherein:
one of the pair of first wires and one of the pair of second wires connect to the through-hole at the starting point; and
another of the pair of first wires and another of the pair of second wires connect to the through-hole at the end point.

6. The wiring board according to claim 5, wherein
a set of the one of the pair of first wires, the one of the pair of second wires, and the through-hole at the starting point, and
a set of the another of the pair of first wires, the another of the pair of second wires, and the through-hole at the end point transmit differential signals.

7. A wiring board manufacturing method comprising:
forming an insulating layer by disposing a fabric that has a planar shape that is translationally symmetric with respect to predetermined two linearly independent translation vectors and encapsulating the fabric by a layered insulating material; and
forming through-holes at starting and end points of a vector that is a sum of substantially integral multiples of each of the two translation vectors and has a starting point on the planar shape.

8. The wiring board manufacturing method according to claim 7, wherein the two translation vectors are substantially perpendicular.

9. The wiring board manufacturing method according to claim 7, further comprising forming each of ground through-holes on a line extended from the vector with a distance substantially equal to the vector from each of the through-holes at the starting and end points.

10. The wiring board manufacturing method according to claim 7, further comprising stacking a plurality of the insulating layers.

11. The wiring board manufacturing method according to claim 10, further comprising:
forming a pair of first wires substantially in parallel on a surface of the insulating layer;
forming a pair of second wires substantially in parallel on a surface of another insulating layer;
connecting one of the pair of first wires and one of the pair of second wires to the through-hole at the starting point; and
connecting another of the pair of first wires and another of the pair of second wires to the through-hole at the end point.

12. The wiring board manufacturing method according to claim 11, wherein a set of the one of the pair of first wires, the one of the pair of second wires, and the through-hole at the starting point, and a set of the another of the pair of first wires, the another of the pair of second wires, and the through-hole at the end point transmit differential signals.

13. The wiring board according to claim 2, further comprising ground through-holes each provided on a line extended from the vector with a distance substantially equal to the vector from each of the through-holes at the starting and end points.

14. The wiring board according to claim 2, wherein a plurality of the insulating layers are stacked.

15. The wiring board according to claim 3, wherein a plurality of the insulating layers are stacked.

16. The wiring board according to claim 13, wherein a plurality of the insulating layers are stacked.

17. The wiring board manufacturing method according to claim 8, further comprising forming each of ground through-holes on a line extended from the vector with a distance substantially equal to the vector from each of the through-holes at the starting and end points.

18. The wiring board manufacturing method according to claim 8, further comprising stacking a plurality of the insulating layers.

19. The wiring board manufacturing method according to claim 9, further comprising stacking a plurality of the insulating layers.

20. The wiring board manufacturing method according to claim 17, further comprising stacking a plurality of the insulating layers.
